(19) United States
(12) Patent Application Publication
(10) Pub. No.: US 2023/0025212 A1
(43) Pub. Date: Jan. 26, 2023

(54) VERTICAL CAVITY SURFACE EMITTING LASER AND METHOD OF MANUFACTURING VERTICAL CAVITY SURFACE EMITTING LASER

(71) Applicant: Sumitomo Electric Industries, Ltd., Osaka (JP)

(72) Inventors: Daisuke INOUE, Osaka-shi (JP); Akito FUJITA, Osaka-shi (JP)

(73) Assignee: Sumitomo Electric Industries, Ltd., Osaka (JP)

(21) Appl. No.: 17/834,037

(22) Filed: Jun. 7, 2022

(30) Foreign Application Priority Data
Jul. 20, 2021 (JP) 2021-119824

(51) Int. Cl. H01S 5/183

(52) U.S. Cl. CPC H01S 5/1833; H01S 5/18311

(57) ABSTRACT

A vertical cavity surface emitting laser includes a first distributed Bragg reflector, an active layer, and a second distributed Bragg reflector. The first distributed Bragg reflector, the active layer and the second distributed Bragg reflector are arranged in sequence in the direction of a first axis. The second distributed Bragg reflector includes a semiconductor region and a high resistance region. The high resistance region has an electrical resistance higher than the electrical resistance of the semiconductor region. The first axis passes through the semiconductor region. The high resistance region surrounds the semiconductor region. In a cross section including the first axis, the high resistance region has an inner edge extending in a direction inclined with respect to the first axis such that an inner diameter of the high resistance region increases as a distance from the active layer increases in the direction of the first axis.

### CROSS REFERENCES TO RELATED APPLICATIONS

The present application claims priority from Japanese Patent Application No. 2021-119824 filed on Jul. 20, 2021, the entire contents of which are hereby incorporated by reference.

### BACKGROUND OF THE INVENTION

### 1. Field of the Invention

The present disclosure relates to a vertical cavity surface emitting laser and a method of manufacturing the vertical cavity surface emitting laser.

### 2. Description of the Related Art

U.S. Patent Application Publication No. 2010/0189147 discloses a vertical cavity surface emitting laser including an n-type distributed Bragg reflector, an active layer, and a p-type distributed Bragg reflector. The n-type distributed Bragg reflector, the active layer, and the p-type distributed Bragg reflector are arranged in sequence in the direction of emission of a laser beam. The p-type distributed Bragg reflector has a semiconductor region and a high resistance region that surrounds the semiconductor region. The high resistance region is formed by ion implantation.

### SUMMARY OF THE INVENTION

In the above-described vertical cavity surface emitting laser, the inner edge of the high resistance region is parallel to the direction of emission of the laser beam. Thus, when the inner edge of the high resistance region is inwardly extended to reduce the capacity of the p-type distributed Bragg reflector, the electrical resistance of the p-type distributed Bragg reflector is increased. Therefore, it is not possible to reduce the capacity of the p-type distributed Bragg reflector while inhibiting an increase in electrical resistance of the p-type distributed Bragg reflector.

The present disclosure provides a vertical cavity surface emitting laser and a method of manufacturing the vertical cavity surface emitting laser that are capable of reducing the capacity of a distributed Bragg reflector while inhibiting an increase in electrical resistance of the distributed Bragg reflector.

A vertical cavity surface emitting laser according to an aspect of the present disclosure includes: a first distributed Bragg reflector; an active layer; and a second distributed Bragg reflector. The first distributed Bragg reflector, the active layer, and the second distributed Bragg reflector are arranged in sequence in a direction of a first axis, the second distributed Bragg reflector includes a semiconductor region and a high resistance region, the high resistance region has an electrical resistance higher than an electrical resistance of the semiconductor region, the first axis passes through the semiconductor region, the high resistance region surrounds the semiconductor region, and in a cross section including the first axis, the high resistance region has an inner edge extending in a direction inclined with respect to the first axis such that an inner diameter of the high resistance region increases as a distance from the active layer increases in the direction of the first axis.

A method of manufacturing a vertical cavity surface emitting laser according to another aspect of the present disclosure includes: forming a mask on a semiconductor layered body provided on a principal surface of a substrate, the semiconductor layered body including a first semiconductor layer for a first distributed Bragg reflector, an active layer, and a second semiconductor layer for a second distributed Bragg reflector and arranging the substrate, the first semiconductor layer, the active layer, the second semiconductor layer, and the mask in sequence in a direction of a first axis intersecting the principal surface; implanting first ions into the second semiconductor layer by using the mask in a first direction inclined with respect to the first axis; and implanting second ions into the second semiconductor layer by using the mask in a second direction inclined with respect to the first axis. A direction obtained by projecting the second direction onto a plane perpendicular to the first axis is different from a direction obtained by projecting the first direction onto the plane.

### BRIEF DESCRIPTION OF THE DRAWINGS

FIG. 1 is a sectional view schematically illustrating a vertical cavity surface emitting laser according to an embodiment.

FIG. 2 is an enlarged sectional view illustrating part of the vertical cavity surface emitting laser of FIG. 1.

FIG. 3 is a plan view illustrating a high resistance region of the vertical cavity surface emitting laser of FIG. 1.

FIG. 4 is a cross section illustrating a step in a method of manufacturing the vertical cavity surface emitting laser according to the embodiment.

FIG. 5 is a cross section illustrating a step in the method of manufacturing the vertical cavity surface emitting laser according to the embodiment.

FIG. 6 is a plan view illustrating the step of FIG. 5.

FIG. 7 is a plan view illustrating a step in the method of manufacturing the vertical cavity surface emitting laser according to the embodiment.

FIG. 8 is a plan view illustrating a step in the method of manufacturing the vertical cavity surface emitting laser according to the embodiment.

### DESCRIPTION OF THE PREFERRED EMBODIMENTS

### Description of Embodiment of the Present Disclosure

A vertical cavity surface emitting laser according to an embodiment includes: a first distributed Bragg reflector; an active layer; and a second distributed Bragg reflector. The first distributed Bragg reflector, the active layer, and the second distributed Bragg reflector are arranged in sequence in a direction of a first axis, the second distributed Bragg reflector includes a semiconductor region and a high resistance region, the high resistance region has an electrical resistance higher than an electrical resistance of the semiconductor region, the first axis passes through the semiconductor region, the high resistance region surrounds the semiconductor region, and in a cross section including the first axis, the high resistance region has an inner edge extending in a direction inclined with respect to the first axis such that an inner diameter of the high resistance region increases as a distance from the active layer increases in the direction of the first axis.

According to the above-described vertical cavity surface emitting laser, the capacity of a portion, close to the active layer, of the second distributed Bragg reflector can be reduced while inhibiting the increase in electrical resistance of a portion, away from the active layer, of the second distributed Bragg reflector. Therefore, it is possible to reduce the capacity of the second distributed Bragg reflector while inhibiting the increase in electrical resistance of the second distributed Bragg reflector.

The high resistance region includes a first high resistance region surrounding the semiconductor region and a second high resistance region surrounding the first high resistance region. The first high resistance region and the second high resistance region each may contain ions, and the ions in the second high resistance region may have a concentration higher than the concentration of the ions in the first high resistance region. In this case, the electrical resistance of the second high resistance region can be made higher than the electrical resistance of the first high resistance region.

The first high resistance region may have a plurality of portions, and concentrations of the ions in the plurality of portions may be different from each other. In this case, the plurality of portions having electrical resistances different from each other are obtained.

The ions in the first high resistance region may have a concentration of 1×10¹⁹ cm⁻³ or more. In this case, the capacity of the second distributed Bragg reflector can be further reduced.

The above-described vertical cavity surface emitting laser further includes an electrode provided to surround the first axis. In the direction of the first axis, the second distributed Bragg reflector may be disposed between the electrode and the active layer, the inner edge of the high resistance region may have a first end and a second end in the cross section, the second end may be located further away from the electrode than the first end in the direction of the first axis, and the first end may be located further away from the first axis than the inner edge of the electrode in a direction perpendicular to the first axis. In this case, the increase in electrical resistance of the second distributed Bragg reflector can be further inhibited.

The second end is located closer to the first axis than the inner edge of the electrode in the direction perpendicular to the first axis. In this case, the capacity of the second distributed Bragg reflector can be further reduced.

A method of manufacturing a vertical cavity surface emitting laser according to an embodiment includes: forming a mask on a semiconductor layered body provided on a principal surface of a substrate, the semiconductor layered body including a first semiconductor layer for a first distributed Bragg reflector, an active layer, and a second semiconductor layer for a second distributed Bragg reflector and arranging the substrate, the first semiconductor layer, the active layer, the second semiconductor layer, and the mask in sequence in a direction of a first axis intersecting the principal surface; implanting first ions into the second semiconductor layer by using the mask in a first direction inclined with respect to the first axis; and implanting second ions into the second semiconductor layer by using the mask in a second direction inclined with respect to the first axis. A direction obtained by projecting the second direction onto a plane perpendicular to the first axis is different from a direction obtained by projecting the first direction onto the plane.

According to the above-described method of manufacturing the vertical cavity surface emitting laser, the first ions are implanted by ion implantation in the first direction into a first part covered with a mask. In addition, the second ions are implanted by ion implantation in the second direction into a second part covered with the mask. The first part and the second part form the above-mentioned high resistance region in the second distributed Bragg reflector. Consequently, in the vertical cavity surface emitting laser manufactured, the capacity of the second distributed Bragg reflector can be reduced while inhibiting an increase in electrical resistance of the second distributed Bragg reflector.

### Details of Embodiment of the Present Disclosure

Hereinafter an embodiment of the present disclosure will be described in detail with reference to the accompanying drawings. The same symbol is used for the same or equivalent components in description of the drawings, and a redundant description is omitted. In the drawings, XYZ coordinate axes are illustrated as needed. The X-axis, Y-axis, and Z-axis intersect (for instance, intersect perpendicularly) each other.

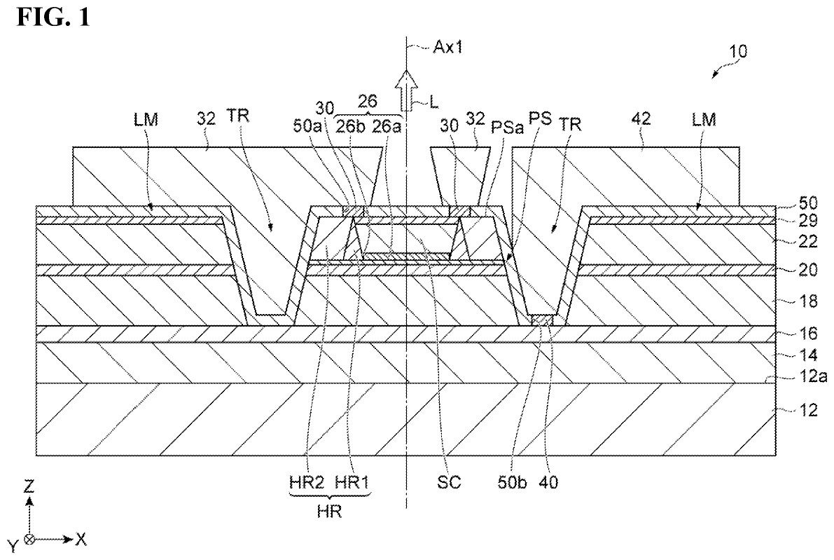

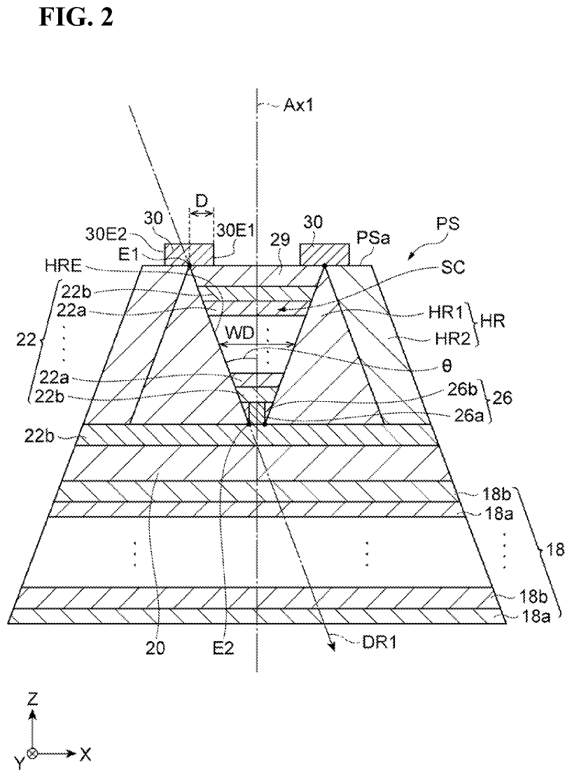

FIG. 1 is a sectional view schematically illustrating a vertical cavity surface emitting laser according to an embodiment. FIG. 2 is an enlarged sectional view illustrating part of the vertical cavity surface emitting laser of FIG. 1. The vertical cavity surface emitting laser (VCSEL) 10 illustrated in FIG. 1 includes a first distributed Bragg reflector 18, an active layer 20, and a second distributed Bragg reflector 22. The first distributed Bragg reflector 18, the active layer 20, and the second distributed Bragg reflector 22 are arranged in sequence in the direction of the first axis Ax1. The direction in which the first axis Ax1 extends matches the Z-axis.

The vertical cavity surface emitting laser 10 may include a post PS provided on a substrate 12. The post PS extends along the first axis Ax1. The post PS includes the first distributed Bragg reflector 18, the active layer 20, and the second distributed Bragg reflector 22. The substrate 12, the first distributed Bragg reflector 18, the active layer 20, and the second distributed Bragg reflector 22 are arranged in sequence in the direction of the first axis Ax1.

The substrate 12 has a principal surface 12a including a III-V compound semiconductor. The principal surface 12a intersects the first axis Ax1. The substrate 12 may be a III-V compound semiconductor substrate. The substrate 12 may be a substrate including a III-V compound semiconductor layer and a base substrate. The III-V compound semiconductor layer has the principal surface 12a. The base substrate supports the III-V compound semiconductor layer. The III-V compound semiconductor includes, for instance, GaAs.

The first distributed Bragg reflector 18 has a semiconductor layered structure of a first conductivity type (for instance, n-type). The semiconductor layered structure includes semiconductor layers 18a and semiconductor layers 18b which are alternately arranged in the direction of the first axis Ax1. A refractive index of the semiconductor layers 18a is different from a refractive index of the semiconductor layers 18b. For instance, the semiconductor layers 18a have a refractive index lower than the refractive index of the semiconductor layers 18b. The semiconductor layers 18a and the semiconductor layers 18b each include a III-V compound semiconductor such as AlGaAs. An example of an n-type dopant is silicon.

The active layer 20 has, for instance, a multiple quantum well structure. The multiple quantum well structure may include GaAs layers (or AlGaAs layers) and AlGaAs layers which are alternately arranged along the first axis Ax1.

The second distributed Bragg reflector 22 has a semiconductor layered structure of a second conductivity type (for instance, p-type). The second conductivity type is a conductivity type opposite to the first conductivity type. The semiconductor layered structure includes semiconductor layers 22a and semiconductor layers 22b which are alternately arranged in the direction of the first axis Ax1. A refractive index of the semiconductor layers 22a is different from a refractive index of the semiconductor layers 22b. For instance, the semiconductor layers 22a have a refractive index lower than the refractive index of the semiconductor layers 22b. The semiconductor layers 22a and the semiconductor layers 22b each include a III-V compound semiconductor such as AlGaAs, for instance.

The post PS may include a contact layer 29 of a second conductivity type (for instance, p-type) provided on the semiconductor layer 22b. The contact layer 29 has an upper surface PSa of the post PS. The contact layer 29 includes a III-V compound semiconductor such as AlGaAs, for instance.

The post PS may include a current narrowing layer 26 disposed between the active layer 20 and the semiconductor layer 22b. The current narrowing layer 26 includes an aperture portion 26a and an oxidation portion 26b that surrounds the aperture portion 26a. The first axis Ax1 passes through the aperture portion 26a. The aperture portion 26a is a semiconductor layer of a second conductivity type (for instance, p-type). The aperture portion 26a includes a III-V compound semiconductor which contains aluminum as a III element. The aperture portion 26a includes a III-V compound semiconductor such as AlGaAs, for instance. The oxidation portion 26b includes aluminum oxide. The aperture portion 26a has an electrical resistance lower than the electrical resistance of the oxidation portion 26b. The inner diameter of the oxidation portion 26b (the outer diameter of the aperture portion 26a) may be 7 μm to 9 μm. The semiconductor layer 22b may be provided between the current narrowing layer 26 and the active layer 20.

A third distributed Bragg reflector 14 may be provided between the substrate 12 and the post PS. The third distributed Bragg reflector 14 has, for instance, a semiconductor layered structure of a first conductivity type (for instance, n-type). The semiconductor layered structure may have an i-type. The semiconductor layered structure includes a plurality of semiconductor layers alternately arranged in the direction of the first axis Ax1. The plurality of semiconductor layers have refractive indices different from each other. Each semiconductor layer includes, for instance, a III-V compound semiconductor such as AlGaAs.

A contact layer 16 of a first conductivity type (for instance, n-type) may be provided between the third distributed Bragg reflector 14 and the post PS. The contact layer 16 includes, for instance, a III-V compound semiconductor such as AlGaAs.

The vertical cavity surface emitting laser 10 may include an electrode 30 which is provided to surround the first axis Ax1. The electrode 30 is, for instance, a ring-shaped electrode. The electrode 30 is provided on the upper surface PSa of the post PS. The second distributed Bragg reflector 22 is disposed between the electrode 30 and the active layer 20 in the direction of the first axis Ax1.

The vertical cavity surface emitting laser 10 may include a semiconductor layered structure LM provided on the principal surface 12a of the substrate 12. The third distributed Bragg reflector 14 and the contact layer 16 are provided between the substrate 12 and the semiconductor layered structure LM. The semiconductor layered structure LM has the same layer structure as that of the post PS. The semiconductor layered structure LM and the post PS are arranged in a direction (for instance, the X-axis) perpendicular to the first axis Ax1. A trench TR surrounding the post PS may be formed between the semiconductor layered structure LM and the post PS. The bottom of the trench TR reaches the contact layer 16.

An insulating layer 50 may be provided on the semiconductor layered structure LM, the trench TR, and the post PS. The insulating layer 50 has a first opening 50a on the upper surface PSa of the post PS. The electrode 30 is provided in the first opening 50a. The insulating layer 50 has a second opening 50b at the bottom of the trench TR. An electrode 40 is provided in the second opening 50b.

The electrode 30 is in ohmic contact with the upper surface PSa of the post PS. The electrode 30 may be electrically connected to a wire 32. The wire 32 extends from the upper surface PSa of the post PS to the semiconductor layered structure LM over the trench TR.

The electrode 40 is in ohmic contact with the contact layer 16. The electrode 40 may be electrically connected to a wire 42. The wire 42 extends from the trench TR to the semiconductor layered structure LM.

The second distributed Bragg reflector 22 includes a semiconductor region SC and a high resistance region HR. The semiconductor region SC includes the semiconductor layer 22a and the semiconductor layer 22b. The first axis Ax1 passes through the center of the semiconductor region SC. The center of the semiconductor region SC may be the centroid of a sectional shape of the semiconductor region SC perpendicular to the first axis Ax1. The semiconductor region SC has, for instance, a circular truncated cone shape. The high resistance region HR has an electrical resistance higher than the electrical resistance of the semiconductor region SC. The high resistance region HR may have a semiconductor of the same type as the semiconductor contained in the semiconductor region SC. The high resistance region HR contains ions. Examples of the ions include proton and a first conductivity type dopant (for instance, n-type dopant).

In a cross section (for instance, XZ cross section) including the first axis Ax1, the high resistance region HR has an inner edge HRE. The inner edge HRE extends in a first direction DR1 inclined with respect to the first axis Ax1. The angle θ formed by the first direction DR1 and the first axis Ax1 may be 7° to 45°. An inner diameter WD of the high resistance region HR increases as the distance from the active layer 20 increases in the direction of the first axis Ax1. The inner diameter WD of the high resistance region HR is the distance between the inner edge HRE and another inner edge opposed to the inner edge HRE in a direction (for instance, the X-axis) perpendicular to the first axis Ax1. Another inner edge may be line symmetric to the inner edge HRE with respect to the first axis Ax1. The inner diameter WD of the high resistance region HR corresponds to the width of the semiconductor region SC in a direction perpendicular to the first axis Ax1. The high resistance region HR may have the inner edge HRE extending in the first direction DR1 in all cross sections (for instance, the YZ cross section) including the first axis Ax1. In all cross sections including the first axis Ax1, the inner diameter WD of the high resistance region HR may increase as the distance from the active layer 20 increases in the direction of the first axis Ax1.

In a cross section including the first axis Ax1, the inner edge HRE of the high resistance region HR has a first end E1 and a second end E2. In the direction (for instance, the Z-axis) of the first axis Ax1, the second end E2 is located further away from the electrode 30 than the first E1.

In a direction (for instance, the X-axis) perpendicular to the first axis Ax1, the first end E1 is located further away from the first axis Ax1 than an inner edge 30E1 of the electrode 30. In a direction perpendicular to the first axis Ax1, the first end E1 may be located closer to the first axis Ax1 than an outer edge 30E2 of the electrode 30. In a direction perpendicular to the first axis Ax1, the distance D between the first end E1 and the inner edge 30E1 of the electrode 30 may be 1 μm to 3 μm. The inner diameter of the electrode 30 may be 12 μm to 22 μm. The outer diameter of the electrode 30 may be 16 μm to 26 μm.

In a direction perpendicular to the first axis Ax1, the second end E2 is located closer to the first axis Ax1 than the first end E1. In a direction perpendicular to the first axis Ax1, the second end E2 may be located closer to the first axis Ax1 than the inner edge 30E1 of the electrode 30.

The high resistance region HR may include a first high resistance region HR1 and a second high resistance region HR2. The first high resistance region HR1 surrounds the semiconductor region SC. The semiconductor region SC and the first high resistance region HR1 may be in contact with each other. The width of the first high resistance region HR1 in a direction (for instance, the X-axis) perpendicular to the first axis Ax1 decreases as the distance from the active layer 20 increases in the direction of the first axis Ax1. The second high resistance region HR2 surrounds the first high resistance region HR1. The first high resistance region HR1 and the second high resistance region HR2 may be in contact with each other. The second high resistance region HR2 has an electrical resistance higher than the electrical resistance of the first high resistance region HR1. The first high resistance region HR1 and the second high resistance region HR2 are, for instance, ring-shaped regions.

The first high resistance region HR1 and the second high resistance region HR2 may each contain ions. The ions in the second high resistance region HR2 have a concentration higher than the concentration of the ions in the first high resistance region HR1. The ions in the first high resistance region HR1 have a concentration of, for instance, 1×10¹⁹ cm⁻³ or more.

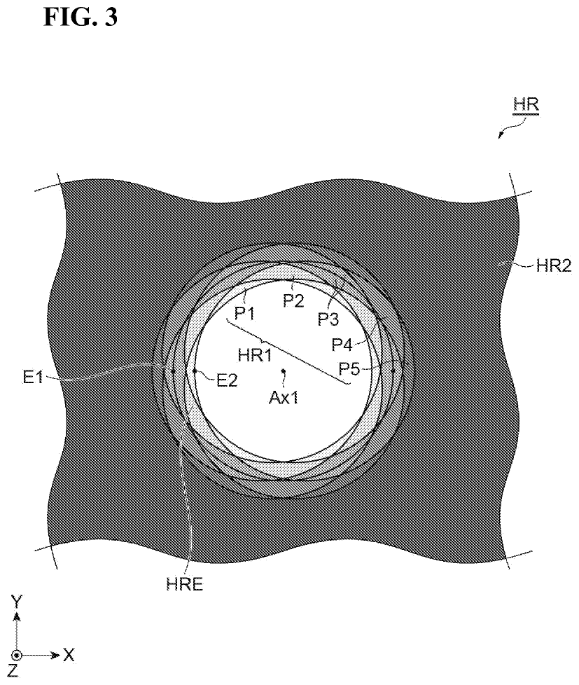

FIG. 3 is a plan view illustrating a high resistance region of the vertical cavity surface emitting laser of FIG. 1. The first high resistance region HR1 may have a first part P1 to a fifth part P5. Concentrations of the ions in the first part P1 to the fifth part P5 are different from each other. The concentrations of the ions in the first part P1 to the fifth part P5 may increase in sequence from the first part P1 to the fifth part P5. The ions in the first part P1 have a concentration of, for instance, 1×10¹⁹ cm⁻³ or more. The concentration of the ions in the second part P2 may be twice the concentration of the ions in the first part P1. The concentration of the ions in the third part P3 may be three times the concentration of the ions in the first part P1. The concentration of the ions in the fourth part P4 may be four times the concentration of the ions in the first part P1. The concentration of the ions in the fifth part P5 may be five times the concentration of the ions in the first part P1.

As illustrated in FIG. 1 and FIG. 2, the high resistance region HR may extend to reach the contact layer 29 and the current narrowing layer 26 in the direction of the first axis Ax1. The high resistance region HR may extend to reach part of the first distributed Bragg reflector 18 in the direction of the first axis Ax1.

In the vertical cavity surface emitting laser 10, when a voltage is applied between the electrode 30 and the electrode 40, a bias current from the electrode 30 flows along the inner edge HRE of the high resistance region HR and is supplied to the active layer 20 through the current narrowing layer 26. Consequently, a laser beam L is emitted in the direction of the first axis Ax1.

With the vertical cavity surface emitting laser 10, it is possible to reduce the capacity of a portion, closer to the active layer 20, of the second distributed Bragg reflector 22 while inhibiting the increase in electrical resistance of a portion, away from the active layer 20, of the second distributed Bragg reflector 22. Thus, the capacity of the second distributed Bragg reflector 22 can be reduced while inhibiting the increase in electrical resistance of the second distributed Bragg reflector 22. Therefore, the vertical cavity surface emitting laser 10 is operable in a wider band. For instance, when the volume of the semiconductor region SC is 874 μm³ and the angle θ formed by the first direction DR1 and the first axis Ax1 is 25°, the capacity of the second distributed Bragg reflector 22 can be reduced by 10 fF, as compared to when the angle θ is 0°.

When the first end E1 of the inner edge HRE of the high resistance region HR is located further away from the first axis Ax1 than the inner edge 30E1 of the electrode 30 in a direction perpendicular to the first axis Ax1, the contact area between the electrode 30 and the upper surface of the semiconductor region SC increases. As a result, the contact resistance can be reduced, and the electrical resistance of the second distributed Bragg reflector 22 can be further reduced.

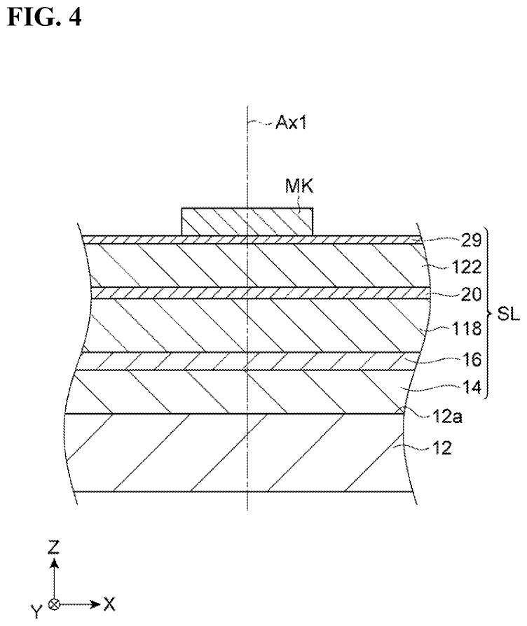

FIG. 4 to FIG. 8 illustrate the steps in a method of manufacturing a vertical cavity surface emitting laser according to an embodiment. The vertical cavity surface emitting laser 10 may be manufactured as follows.

First, as illustrated in FIG. 4, a mask MK is formed on a semiconductor layered body SL provided on the principal surface 12a of the substrate 12. The semiconductor layered body SL includes a first semiconductor layer 118 for the first distributed Bragg reflector 18, the active layer 20, and a second semiconductor layer 122 for the second distributed Bragg reflector 22. The substrate 12, the first semiconductor layer 118, the active layer 20, the second semiconductor layer 122, and the mask MK are arranged in sequence in the direction of the first axis Ax1 intersecting the principal surface 12a. The semiconductor layered body SL may further include the third distributed Bragg reflector 14, the contact layer 16, and the contact layer 29. The third distributed Bragg reflector 14, the contact layer 16, the first semiconductor layer 118, the active layer 20, the second semiconductor layer 122, the contact layer 29, and the mask MK are formed in sequence on the substrate 12. Each semiconductor layer is formed by organometallic vapor phase epitaxy (OMVPE), for instance. The mask MK is, for instance, a resist mask. The first axis Ax1 passes through the mask MK. The mask MK is, for instance, circular as viewed in the direction of the first axis Ax1. The first axis Ax1 may pass through the centroid of the surface shape of the mask MK.

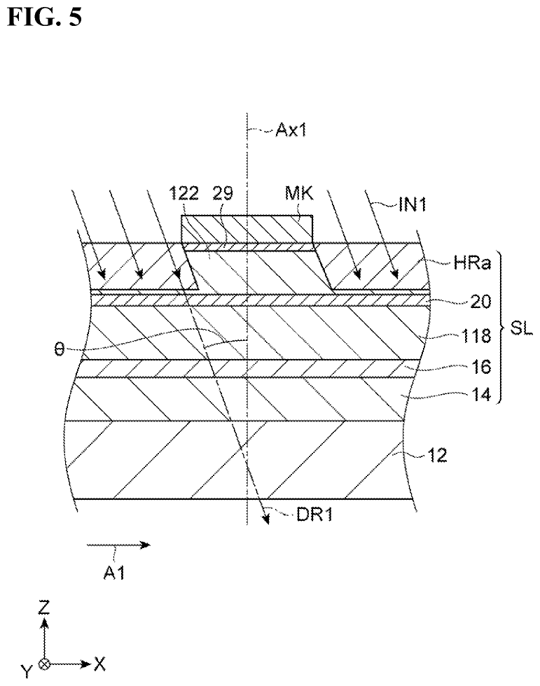

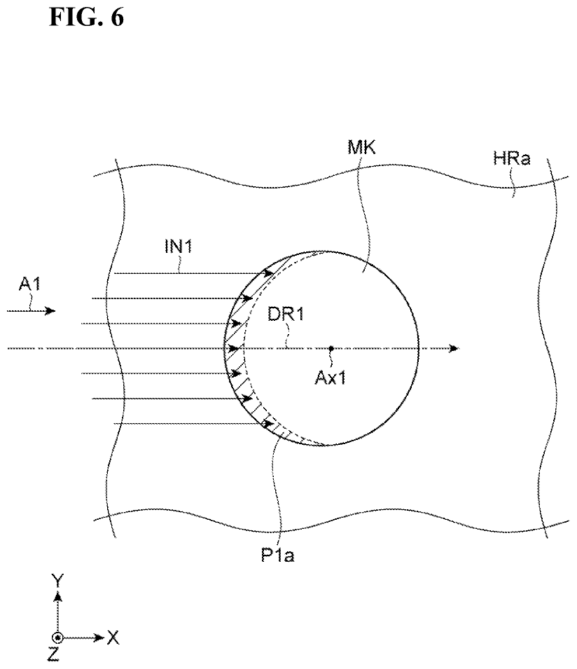

Next, as illustrated in FIG. 5 and FIG. 6, first ions IN1 are implanted into the second semiconductor layer 122 by using the mask MK in the first direction DR1 inclined with respect to the first axis Ax1. Thus, a high resistance region HRa is formed. The first ions IN1 are also implanted into a first part P1a covered with the mask MK as viewed in the direction of the first axis Ax1. The first direction DR1 is inclined with respect to the first axis Ax1 by the angle θ. A direction A1 obtained by projecting the first direction DR1 onto a plane (for instance, the XY plane) perpendicular to the first axis Ax1 matches the positive direction of the X-axis.

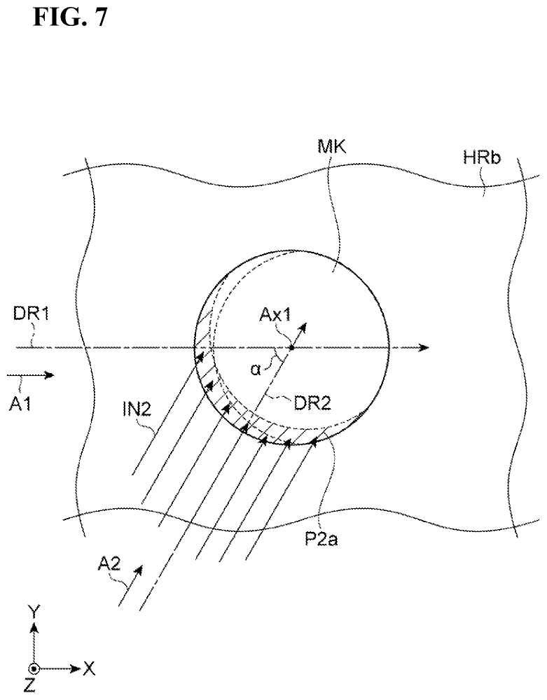

Next, as illustrated in FIG. 7, second ions IN2 are implanted into the second semiconductor layer 122 by using the mask MK in a second direction DR2 inclined with respect to the first axis Ax1. Thus, a high resistance region HRb is formed. The second ions IN2 are also implanted into a second part P2a covered with the mask MK as viewed in the direction of the first axis Ax1. The kind of the second ions IN2 may be the same as the kind of the first ions IN1. The second direction DR2 may be inclined with respect to the first axis Ax1 by the angle θ. A direction A2 obtained by projecting the second direction DR2 onto a plane perpendicular to the first axis Ax1 is different from the direction A1. The implantation of the second ions IN2 is performed after the substrate 12 is relatively rotated with respect to an ion implanter around the first axis Ax1 by an angle α formed by the direction A1 and the direction A2. The angle α formed by the direction A1 and the direction A2 may be 360°/k. k may be an integer of 2 or more, or may be an even number of 4 or more. k may be a divisor of 360. For instance, when k is 6, the angle α is 60°. Let x be the concentration of the ions in the second high resistance region HR2, the dose amount of each ion implantation may be set to x/k.

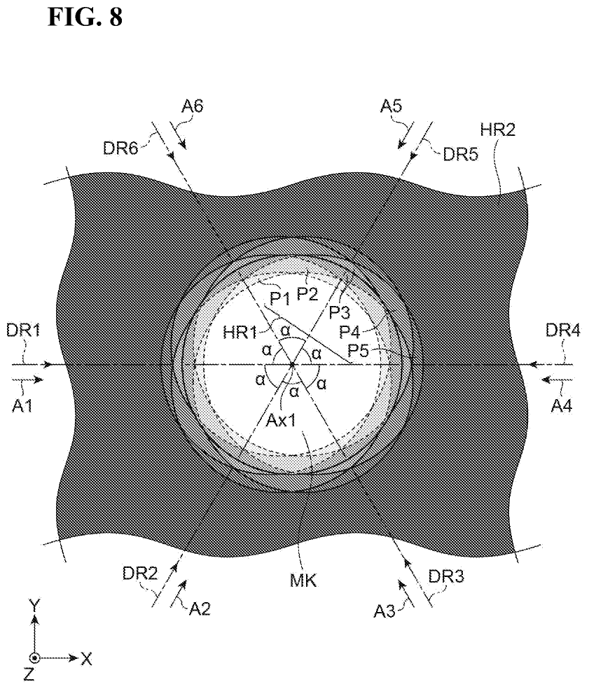

Next, as illustrated in FIG. 8, third ions to sixth ions may be implanted into the second semiconductor layer 122 by using the mask MK in a third direction DR3 to a sixth direction DR6 inclined with respect to the first axis Ax1. The kind of the third ions to the sixth ions may be the same as the kind of the first ions IN1. The third direction DR3 to the sixth direction DR6 may be each inclined with respect to the first axis Ax1 by the angle θ. A direction A3 obtained by projecting the third direction DR3 onto a plane perpendicular to the first axis Ax1 is different from the direction A1 and the direction A2. The implantation of the third ions is performed after the substrate 12 is relatively rotated with respect to the ion implanter around the first axis Ax1 by the angle α formed by the direction A2 and the direction A3. A direction A4 obtained by projecting the fourth direction DR4 onto a plane perpendicular to the first axis Ax1 is different from the direction A1 to the direction A3. The implantation of the fourth ions is performed after the substrate 12 is relatively rotated with respect to the ion implanter around the first axis Ax1 by the angle α formed by the direction A3 and the direction A4. A direction A5 obtained by projecting the fifth direction DR4 onto a plane perpendicular to the first axis Ax1 is different from the direction A1 to the direction A4. The implantation of the fifth ions is performed after the substrate 12 is relatively rotated with respect to the ion implanter around the first axis Ax1 by the angle α formed by the direction A4 and the direction A5. A direction A6 obtained by projecting the sixth direction DR6 onto a plane perpendicular to the first axis Ax1 is different from the direction A1 to the direction A5. The implantation of the sixth ions is performed after the substrate 12 is relatively rotated with respect to the ion implanter around the first axis Ax1 by the angle α formed by the direction A5 and the direction A6. A high resistance region HR having the first high resistance region HR1 and the second high resistance region HR2 is formed by the ion implantation described above. After the ion implantation, the mask MK is removed.

Next, the trench TR illustrated in FIG. 1 is formed by photolithography and etching, for instance. Thus, the post PS and the semiconductor layered structure LM are formed. Subsequently, the oxidation portion 26b of the current narrowing layer 26 is formed by oxidizing the lateral surface of the post PS. Subsequently, the insulating layer 50 is formed. Subsequently, the electrode 30 and the electrode 40 are formed. Subsequently, the wire 32 and the wire 42 are formed.

According to the above-described method of manufacturing the vertical cavity surface emitting laser 10, as illustrated in FIG. 6, the first ions IN1 are implanted by ion implantation in the first direction DR1 into the first part P1a covered with the mask MK. In addition, as illustrated in FIG. 7, the second ions IN2 are implanted by ion implantation in the second direction DR2 into the second part P2a covered with the mask MK. The high resistance region HR is formed in the second distributed Bragg reflector 22 by the ion implantation. Thus, in the vertical cavity surface emitting laser 10 to be manufactured, the capacity of the second distributed Bragg reflector 22 can be reduced while inhibiting the increase in electrical resistance of the second distributed Bragg reflector 22. In addition, ion implantation can be performed multiple times by using the same mask MK, and thus it is not necessary to produce a mask for each ion implantation. Therefore, the time taken for ion implantation can be reduced.

Although a preferred embodiment of the present disclosure has been described in detail above, the present disclosure is not limited to the embodiment.

It is to be understood that the embodiment disclosed herein is illustrative and not restrictive in all respects. It is intended that the scope of the present disclosure be defined by the appended claims rather than the foregoing description, and that all changes within the meaning and range of equivalency of the claims be embraced therein.

What is claimed is:

1. A vertical cavity surface emitting laser comprising:
a first distributed Bragg reflector;
an active layer; and
a second distributed Bragg reflector,
wherein the first distributed Bragg reflector, the active layer, and the second distributed Bragg reflector are arranged in sequence in a direction of a first axis,
the second distributed Bragg reflector includes a semiconductor region and a high resistance region,
the high resistance region has an electrical resistance higher than an electrical resistance of the semiconductor region,
the first axis passes through the semiconductor region,
the high resistance region surrounds the semiconductor region, and
in a cross section including the first axis, the high resistance region has an inner edge extending in a direction inclined with respect to the first axis such that an inner diameter of the high resistance region increases as a distance from the active layer increases in the direction of the first axis.

2. The vertical cavity surface emitting laser according to claim 1,
wherein the high resistance region includes a first high resistance region surrounding the semiconductor region and a second high resistance region surrounding the first high resistance region,
the first high resistance region and the second high resistance region each contain ions, and
the ions in the second high resistance region have a concentration higher than a concentration of the ions in the first high resistance region.

3. The vertical cavity surface emitting laser according to claim 2,
wherein the first high resistance region has a plurality of portions, and concentrations of the ions in the plurality of portions are different from each other.

4. The vertical cavity surface emitting laser according to claim 2,
wherein the ions in the first high resistance region have a concentration of 1×10¹⁹ cm⁻³ or more.

5. The vertical cavity surface emitting laser according to claim 1, further comprising an electrode provided to surround the first axis,
wherein the second distributed Bragg reflector is disposed between the electrode and the active layer in the direction of the first axis,
the inner edge of the high resistance region has a first end and a second end in the cross section,
the second end is located further away from the electrode than the first end in the direction of the first axis, and
the first end is located further away from the first axis than the inner edge of the electrode in a direction perpendicular to the first axis.

6. The vertical cavity surface emitting laser according to claim 5,
wherein the second end is located closer to the first axis than the inner edge of the electrode in the direction perpendicular to the first axis.

7. A method of manufacturing a vertical cavity surface emitting laser, the method comprising:
forming a mask on a semiconductor layered body provided on a principal surface of a substrate, the semiconductor layered body including a first semiconductor layer for a first distributed Bragg reflector, an active layer, and a second semiconductor layer for a second distributed Bragg reflector and arranging the substrate, the first semiconductor layer, the active layer, the second semiconductor layer, and the mask in sequence in a direction of a first axis intersecting the principal surface;
implanting first ions into the second semiconductor layer by using the mask in a first direction inclined with respect to the first axis; and
implanting second ions into the second semiconductor layer by using the mask in a second direction inclined with respect to the first axis,
wherein a direction obtained by projecting the second direction onto a plane perpendicular to the first axis is different from a direction obtained by projecting the first direction onto the plane.
